(19) United States
(12) Patent Application Publication
(10) Pub. No.: US 2008/0067574 A1
(43) Pub. Date: Mar. 20, 2008

(54) Semiconductor device and method for manufacturing the same

(76) Inventor: Chiaki Kudo, Hyogo (JP)

Correspondence Address: MCDERMOTT WILL & EMERY LLP, 600 13TH STREET, NW, WASHINGTON, DC, 20005-3096, US

(21) Appl. No.: 11/819,190

(22) Filed: Jun. 26, 2007

(30) Foreign Application Priority Data
Sep. 20, 2006 (JP) 2006-253997

(51) Int. Cl. H01L 29/788; H01L 21/44

(52) U.S. Cl. 257/316; 438/664; 257/E29.3; 257/E21.476

(57) ABSTRACT

A semiconductor device includes a first conductor and a second conductor electrically connected to each other to have the same potential. At least one of the first and second conductors has a fully silicided (FUSI) structure. A step having an overhang is formed at least at part of a boundary between the first and second conductors.

### BACKGROUND OF THE INVENTION

1. Field of the Invention

The present invention relates to a semiconductor device including a fully silicided (FUSI) FET (field-effect transistor) and resistance element and a method for manufacturing the same.

2. Description of Related Art

As semiconductor elements are integrated to a higher degree, gate electrodes are scaled down and the electrical thickness of a gate insulating film is reduced. In this trend, for example, if polysilicon is used for the gate electrode, depletion occurs inevitably in the polysilicon gate electrode even if impurities are implanted therein. The depletion increases the electrical thickness of the gate insulating film. This has been an obstacle to improvement in performance of the FET.

In recent years, various gate electrode structures have been proposed for the purpose of preventing the depletion of the gate electrode. For example, a fully silicided (FUSI) gate electrode obtained by reacting silicon used for the gate electrode with metal for full silicidation of the silicon has been reported as an effective means of suppressing the depletion.

For example, methods for manufacturing the FUSI gate electrode have been proposed by Japanese Unexamined Patent Publication No. 2000-252462 (Patent Literature 1) and T. Aoyama et al., Proposal of New HfSiON CMOS Fabrication Process (HAMDAMA) for Low Standby Power Device, 2004, IEEE (Nonpatent Literature 1). Further, use of different materials for FUSI gate electrodes of n- and p-FETs has been proposed. Specifically, NiSi is used for the n-FET FUSI gate electrode and Ni₃Si is used for the p-FET FUSI gate electrode (see K. Takahashi et al., Dual Workfunction Ni-Silicide/HfSiON Gate Stacks by Phase-Controlled Full-Silicidation (PC-FUSI) Technique for 45 nm-node LSTP and LOP Devices, 2004, IEEE (Nonpatent Literature 2) and J. A. Kittl et al., Scalability of Ni FUSI gate process: phase and Vt control to 30 nm gate lengths, 2005 Symposium on VLSI Technology Digest of Technical Papers pp. 72-73, (Nonpatent Literature 3)).

FIGS. 8A to 8D are sectional views illustrating the steps of manufacturing a FET having a conventional FUSI gate electrode according to Nonpatent Literature 1.

In the step of the conventional method shown in FIG. 8A, an n-FET region R1 and a p-FET region R2 are defined by forming an isolation region 2 in a semiconductor substrate 1 and a gate insulating film 4 and a silicon film 7 are formed on the semiconductor substrate 1. Then, the silicon film 7 is patterned using a resist pattern (not shown) covering a region for forming the gate electrode. Sidewall spacers 21 are then formed on the sidewalls of the patterned silicon film 7 and source/drain regions 22 are formed in parts of the surface of the semiconductor substrate 1 on both sides of the region for forming the gate electrode. An interlayer insulating film 9 is formed on the entire surface of the semiconductor substrate 1 and polished by CMP (chemical mechanical polishing) to expose the surface of the silicon material film 7 to be the gate electrode.

In the step of FIG. 8B, an upper part of the silicon film 7 in the p-FET region R2 is removed by etching using a photoresist film 24 having an opening only above the p-FET region R2 as a mask.

After the photoresist film 24 is removed, a nickel film is deposited as a metallic film 15 on the silicon film 7 and the interlayer insulating film 9 in the step of FIG. 8C.

In the step of FIG. 8D, thermal treatment is performed to cause reaction between the silicon film 7 and the metallic film 15 to form a silicide film 25.

Nonpatent Literature 1 further discloses that a laminated structure of the silicon film 7 made of polysilicon and the silicide film 25 made of NiSi is provided as the gate electrode on the gate insulating film 4 of the n-FET region and a single layer FUSI structure of the silicide film 25 made of NiSi is provided as the gate electrode on the gate insulating film 4 of the p-FET region.

Further, in the step of FIG. 8C, a thick nickel film is deposited as the metallic film 15 to form a FUSI structure of NiSi as the n-FET gate electrode and a FUSI structure of Ni₃Si as the p-FET gate electrode.

### SUMMARY OF THE INVENTION

In a flip-flop, the n-FET gate electrode and the p-FET gate electrode may be configured to have the same potential. In this case, the n- and p-FET gate electrodes are directly connected to each other for area reduction.

According to the above-described conventional method, however, silicide as the n-FET gate electrode and silicide as the p-FET gate electrode have different silicon/metal ratios. Therefore, during the silicidation or subsequent thermal treatment, metal may be diffused from a silicide region having relatively high metal concentration to a silicide region having relatively low metal concentration. In particular, when the silicide region with relatively high metal concentration is fully silicided and the silicide region with relatively low metal concentration is not fully silicided, the metal diffusion significantly occurs at a boundary therebetween. Due to the metal diffusion, part of the FET gate electrode contacting the gate insulating film may vary in silicide composition from the other parts. This leads to variations in threshold voltage.

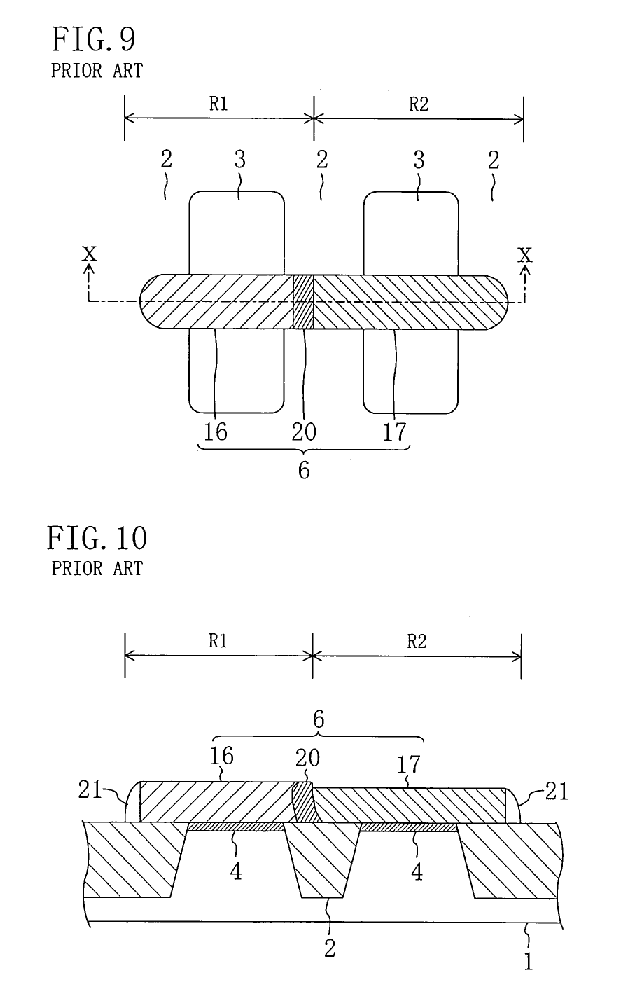

FIG. 9 is a plan view for explaining a problem involved in the conventional method and FIG. 10 is a sectional view taken along the line X-X of FIG. 9. In FIGS. 9 and 10, the n-FET gate electrode has a FUSI structure of NiSi and the p-FET gate electrode has a FUSI structure of Ni₃Si.

As shown in FIGS. 9 and 10, an isolation region 2 is formed in a semiconductor substrate 1 to define an n-FET region R1 and a p-FET region R2. Parts of the semiconductor substrate 1 surrounded by the isolation region 2 are active regions 3. A gate electrode 6 is formed to pass across the active regions 3 in the n- and p-FET regions R1 and R2. A gate insulating film 4 is interposed between the semiconductor substrate 1 and the gate electrode 6. Sidewall spacers 21 are formed on the sidewalls of the gate electrode 6.

The gate electrode 6 includes a first conductor 16 as the n-FET gate electrode and a second conductor 17 as the p-FET gate electrode connected to each other. The first conductor 16 has the FUSI structure of NiSi and the second conductor 17 has the FUSI structure of Ni₃Si.

During the silicidation or subsequent thermal treatment, Ni is diffused from the second conductor 17 having relatively high Ni concentration to the first conductor 16 having relatively low Ni concentration. As a result, an intermediate phase region 20 having an intermediate composition between compositions of the first and second conductors 16 and 17 (NiSi and Ni₃Si) is formed between the first and second conductors 16 and 17. If the intermediate phase region 20 is formed large, part of the FET gate electrode in contact with the gate insulating film 4 may vary in silicide composition. This leads to variations in threshold voltage.

If the n- and p-FET gate electrodes are connected via wires or a distance between the n- and p-FET gate electrodes is increased (the isolation region between them is increased) to prevent failure caused by the metal diffusion, another problem of increase in circuit area arises.

Thus, in a semiconductor device including two conductors electrically connected to each other to have the same potential with at least one of which being fully silicided, an object of the present invention is to suppress the occurrence of an intermediate phase region caused by metal diffusion at a boundary between the conductors.

In order to achieve the object, the inventor of the present invention has made the following finding as a result of close study on a mechanism of the occurrence of the intermediate phase region.

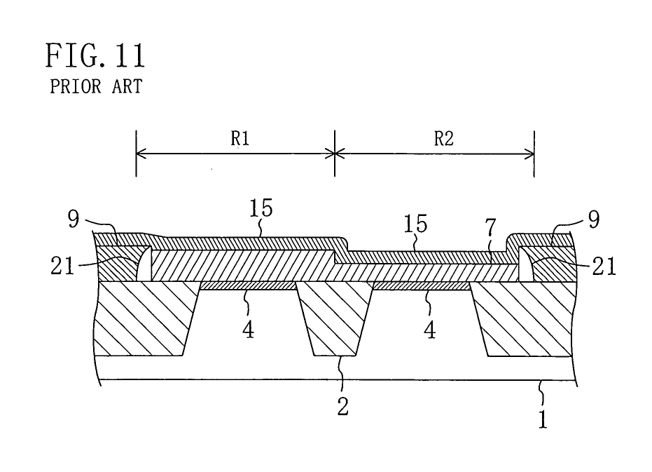

FIG. 11 is a view for explaining the mechanism of the occurrence of the intermediate phase region according to the conventional art. FIG. 11 is a sectional view illustrating the step corresponding to the step shown in FIG. 8C in which the n- and p-FET gate electrodes are directly connected to each other. In FIG. 11, the same components as those shown in FIGS. 8A to 8D are indicated by the same reference numerals to omit overlapping explanation.

Referring to FIG. 11, part of the silicon film 7 in the p-FET region R2 is thinner than part of the silicon film 7 in the n-FET region R1 and a step is formed at a boundary therebetween. If the metallic film (nickel film) 15 is deposited thereon, it is deposited thickly also on a riser of the step. Therefore, a larger amount of metal is supplied to the silicon film 7 (the silicon film 7 in the n-FET region R1) from the metallic film 15 on the riser of the step. As a result, an intermediate phase region is increased toward the n-FET region R1.

In view of the above, the inventor of the present invention has conceived that the step formed in the silicon film at the boundary of the n- and p-FET regions is configured to have an overhang, i.e., the step is formed to have an overhanging portion, so that the metallic film deposited on the riser of the step is reduced in thickness and the intermediate phase region is less likely to occur. The shape of the overhang of the step formed in the silicon film remains in a silicide film obtained after the silicidation.

More specifically, a semiconductor device according to the present invention includes a first conductor and a second conductor electrically connected to each other to have the same potential, wherein at least one of the first and second conductors has a fully silicided (FUSI) structure and a step having an overhang is formed at least at part of a boundary between the first and second conductors.

In the manufacture of the semiconductor device according to the present invention, a step having an overhang is formed in a silicon film at a boundary between parts of the silicon film to become conductors prior to the deposition of a metallic film used for silicidation. Therefore, the metallic film deposited on the riser of the step at the boundary is reduced in thickness. As a result, the amount of metal supplied to the vicinity of the boundary during the silicidation is reduced and the occurrence of an intermediate phase region is suppressed. If the present invention is applied to FET, characteristic variations such as variations in threshold voltage are reduced without increasing the circuit area.

As to the semiconductor device of the present invention, a region having an intermediate composition between compositions of the first and second conductors may be interposed between the first and second conductors.

As to the semiconductor device of the present invention, the first conductor may have a first FUSI structure of NiSi and the second conductor may have a second FUSI structure of NiₓSi (x>1).

As to the semiconductor device of the present invention, the first and second conductors may be gate electrodes of MISFETs and the gate electrodes may be formed on a gate insulating film having a high dielectric constant.

As to the semiconductor device of the present invention, the first and second conductors may be fuse elements or resistance elements.

A method for manufacturing a semiconductor device according to the present invention may be a method for manufacturing a semiconductor device having a first conductor and a second conductor electrically connected to each other to have the same potential. The method may include the steps of: (a) forming a silicon film on a substrate; (b) shaping the silicon film into a pattern including parts to become the first and second conductors; (c) reducing a thickness of the part of the silicon film to become the second conductor after the step (b); (d) forming a metallic film on the silicon film after the step (c); and (e) reacting the metallic film with the silicon film by thermal treatment to cause full silicidation of at least the part of the silicon film to become the second conductor after the step (d), wherein in the step (d), the metallic film is deposited more thinly than on the other parts or not deposited at all on a riser of a step formed in the silicon film in the step (c).

According to the method of the present invention, the metallic film is deposited more thinly than on the other parts or not deposited at all on the riser of the step formed in the silicon film at the boundary between parts of the silicon film to become the conductors. As a result, the amount of metal supplied to the vicinity of the boundary during the silicidation is reduced and the occurrence of an intermediate phase region is suppressed. For example, in a semiconductor device formed by the method of the present invention, conductors formed on active regions (on a gate insulating film) of the FETs to function as the gate electrodes have uniform silicide composition. This makes it possible to reduce the variations in threshold voltage of the FETs.

As to the method of the present invention, the step formed in the silicon film in the step (c) preferably has an overhang.

With this configuration, the above-described effect is obtained with reliability.

As to the method of the present invention, the metallic film may be a Ni film.

According to the semiconductor device of the present invention described above, the step having the overhang is formed at the boundary between FUSI electrodes having different compositions (one of them may be non-FUSI gate electrode). Therefore, the amount of metal supplied to the vicinity of the boundary during the silicidation is reduced. As a result, even if the circuit area is not increased, the intermediate phase region is less likely to occur and the characteristic variations are reduced.

Further, according to the method for manufacturing the semiconductor device of the present invention, the occurrence of the intermediate phase region due to the metal diffusion is suppressed by a simple means of forming an overhang on the step formed in the silicon film at the boundary between parts of the silicon film to become the conductors prior to the deposition of the metallic film.

Namely, the present invention relates to a semiconductor device including an FET, a resistance element or the like and a method for manufacturing the same. If the present invention is applied to a semiconductor device including two conductors electrically connected to each other to have the same potential with at least one of which being fully silicided, the present invention exhibits a significant effect of suppressing the occurrence of an intermediate phase region caused by metal diffusion. Thus, the present invention is very useful. BRIEF DESCRIPTION OF THE DRAWINGS

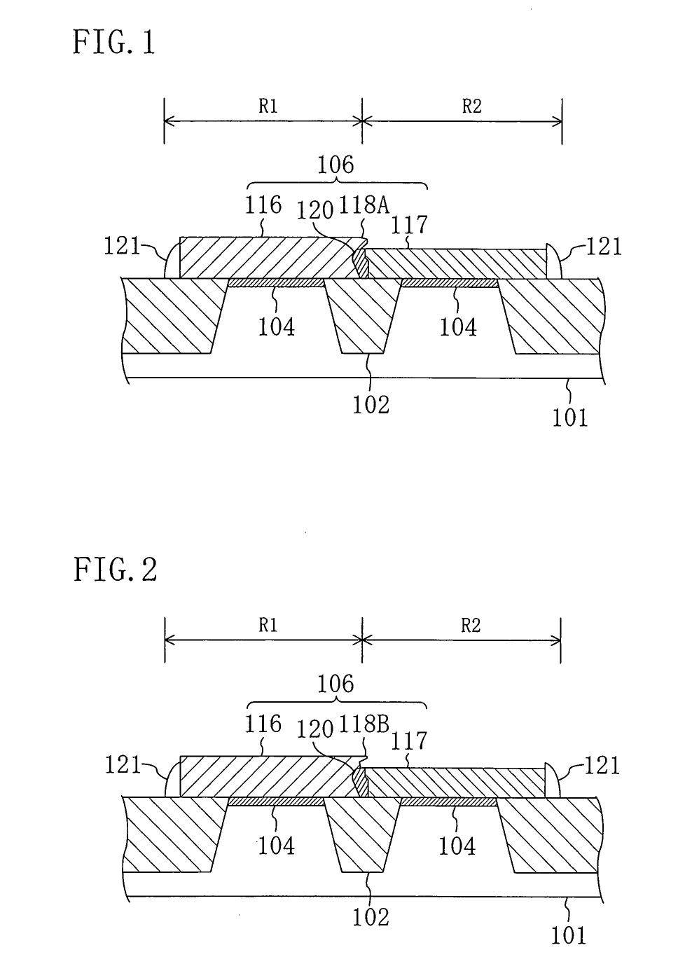

FIG. 1 is a schematic sectional view illustrating the structure of a semiconductor device according to an embodiment of the present invention.

FIG. 2 is a schematic sectional view illustrating the structure of the semiconductor device according to a modification of the embodiment of the present invention.

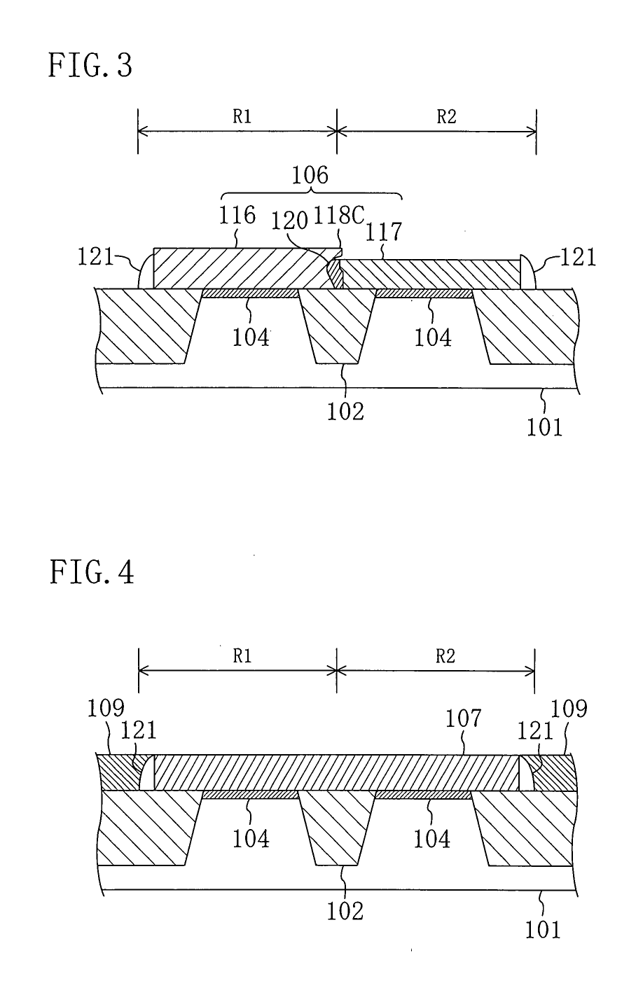

FIG. 3 is a schematic sectional view illustrating the structure of the semiconductor device according to a modification of the embodiment of the present invention.

FIG. 4 is a schematic sectional view illustrating a step of manufacturing a FET in a method for manufacturing the semiconductor device according to the embodiment of the present invention.

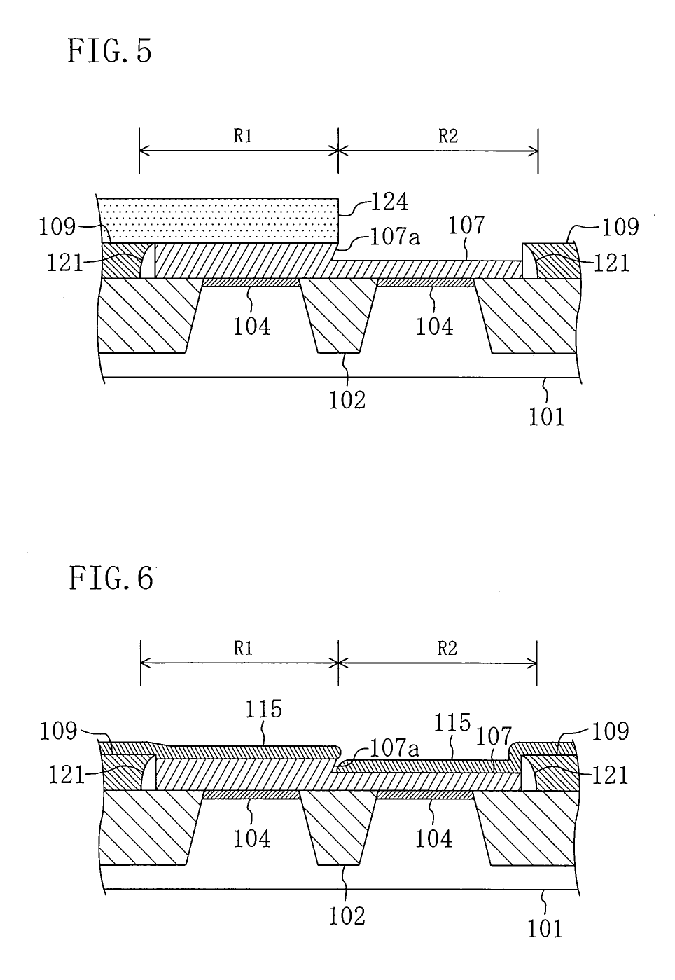

FIG. 5 is a schematic sectional view illustrating a step of manufacturing the FET in the method for manufacturing the semiconductor device according to the embodiment of the present invention.

FIG. 6 is a schematic sectional view illustrating a step of manufacturing the FET in the method for manufacturing the semiconductor device according to the embodiment of the present invention.

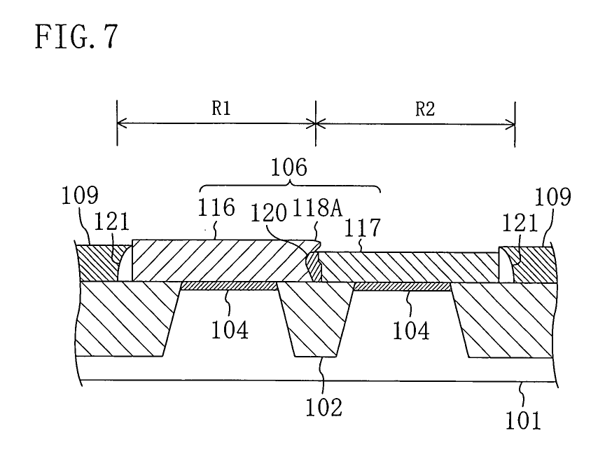

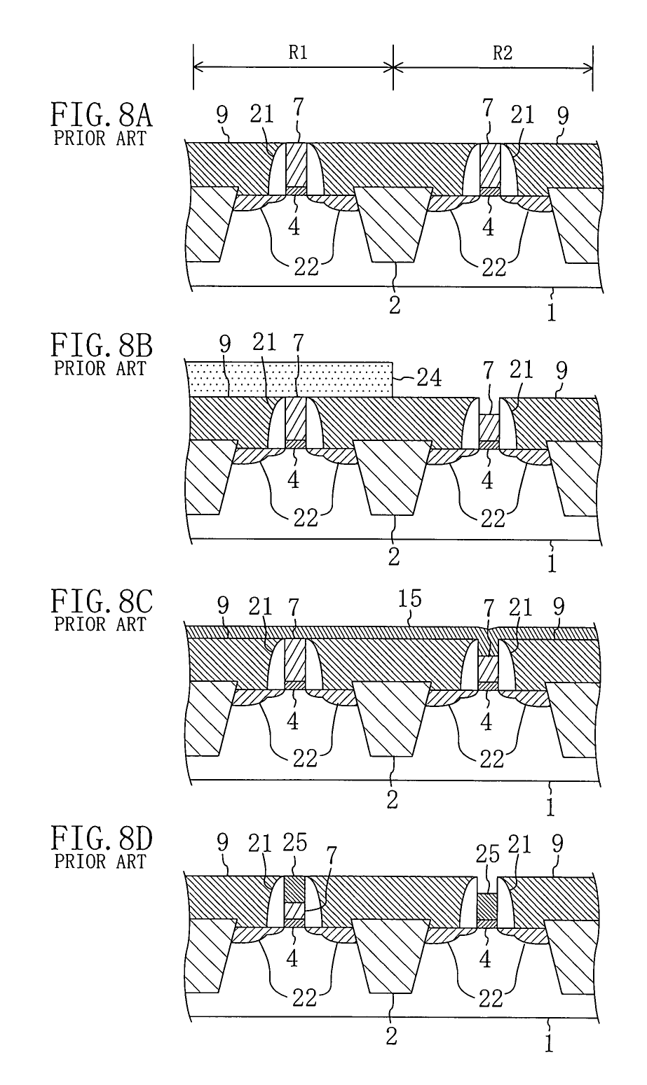

FIG. 7 is a schematic sectional view illustrating a step of manufacturing the FET in a method for manufacturing the semiconductor device according to the embodiment of the present invention.

FIGS. 8A to 8D are sectional views illustrating the steps of manufacturing a FET having a conventional FUSI electrode.

FIG. 9 is a plan view for explaining a problem involved in a conventional art.

FIG. 10 is a sectional view taken along the line X-X of FIG. 9.

FIG. 11 is a view for explaining a mechanism of occurrence of an intermediate phase region according to the conventional art.

### DETAILED DESCRIPTION OF THE INVENTION

### Embodiment

Hereinafter, explanation of an embodiment of the semiconductor device according to the present invention is provided with reference to the drawings. In this embodiment, a semiconductor device having a FET is taken as an example.

FIG. 1 is a schematic sectional view illustrating the structure of the semiconductor device according to the present embodiment. As shown in FIG. 1, an isolation region 102 is formed in a semiconductor substrate 101 to define an n-FET region R1 and a p-FET region R2. A gate electrode 106 shared between the n- and p-FETs is formed on the semiconductor substrate 101. A gate insulating film 104 made of highly dielectric material such as HfO₂ is interposed between active regions in the semiconductor substrate 101 and the gate electrode 106. Sidewall spacers 121 are formed on the sidewalls of the gate electrode 106.

The gate electrode 106 includes a first conductor 116 and a second conductor 117 electrically connected to each other to have the same potential. The first conductor 116 functions as an n-FET gate electrode and has a fully silicided (FUSI) structure of NiSi and the second conductor 117 functions as a p-FET gate electrode and has a FUSI structure of NiₓSi (x>1). The first conductor 116 is thicker than the second conductor 117 and a step is formed at a boundary between them. Further, an intermediate phase region 120 is formed on the isolation region 102 at a boundary between the n- and p-FET regions R1 and R2. Specifically, the intermediate phase region 120 is formed between the first and second conductors 116 and 117 and has an intermediate composition between compositions of the first and second conductors 116 and 117 (intermediate composition between NiSi and Ni₃Si or Ni₂Si, for example).

In FIG. 1, well regions, source/drain regions and implantation regions for threshold control formed in the n- and p-FET regions R1 and R2 are not depicted for the sake of easy illustration.

As a feature of the present embodiment, the step formed at the boundary between the first and second conductors 116 and 117 has an overhang 118A protruding toward the second conductor 117. Specifically, the step is formed to have an overhanging portion. Further, an upper part of the intermediate phase region 120 protrudes toward the first conductor 116 for the reason described later.

Referring to FIG. 1, the overhang 118A is formed in a range from the top surface of the first conductor 116 to the top surface of the second conductor 117. However, the shape of the overhang that exhibits the effect of the present invention is not limited thereto. FIGS. 2 and 3 are schematic sectional views illustrating the structures of the semiconductor device according to the modifications of the present embodiment. In FIGS. 2 and 3, the same components as those shown in FIG. 1 are indicated by the same reference numerals to omit overlapping explanation. FIG. 2 shows an overhang 118B formed only near the top surface of the first conductor 116. FIG. 3 shows an overhang 118C formed in a range from the top surface of the first conductor 116 to the top surface of the second conductor 117. The overhang 118C of FIG. 3 has a square cross section, while the overhang 118A shown in FIG. 1 is tapered to have an acute angle when viewed in section.

According to the semiconductor device of the present embodiment described above, the step having the overhang 118 is formed at the boundary between the first and second conductors 116 and 117. That is, in the manufacture of the semiconductor device of the present embodiment, the step having the overhang is formed in a silicon film for forming the conductors at a boundary between parts of the silicon films to become the conductors prior to the deposition of a metallic film used for silicidation. Therefore, the metallic film is deposited thinly on a riser of the step (including the overhang) and part of the silicon film below the overhang. As a result, the amount of metal supplied to the vicinity of the boundary during silicidation is reduced and the occurrence of the intermediate phase region 120 is suppressed. This makes it possible to reduce variations in threshold voltage of the FET without increasing the circuit area. Therefore, the semiconductor device is improved in performance and integrated to a higher degree.

Now, a method for manufacturing the semiconductor device of the present embodiment is provided with reference to the drawings, while taking a semiconductor device having a FET as an example.

FIGS. 4 to 7 are schematic sectional views illustrating the steps of the method for manufacturing the semiconductor device according to the present embodiment. The sectional views are taken along the gate width direction.

In the step shown in FIG. 4 according to the method for manufacturing the semiconductor device of the present embodiment, an isolation region 102 is formed in a silicon semiconductor substrate 101 by a known method to define an n-FET region R1 and a p-FET region R2. Then, a HfO₂ film is deposited as a gate insulating film 104 on an active region of the semiconductor substrate 101 and a polysilicon film having a thickness of 75 nm, for example, is deposited as a silicon film 107. Then, the silicon film 107 is patterned using a resist pattern (not shown) covering a region for forming a gate electrode. Sidewall spacers 121 are formed on the sidewalls of the patterned silicon film 107 and source/drain regions (not shown) are formed in parts of the surface of the semiconductor substrate 101 on the sides of the region for forming the gate electrode by a known method. Then, an interlayer insulating film 109 is formed on the entire surface of the semiconductor substrate 101 and planarized by CMP, for example, to expose the top surface of the silicon film 107 to be the gate electrode.

In the step shown in FIG. 4, well regions, implantation regions for threshold control and the like are formed in the n- and p-FET regions R1 and R2, respectively, but they are not depicted in the Figure for the sake of easy illustration. Impurities may be implanted into the silicon film 107 before the end of the step of FIG. 4.

In the step shown in FIG. 5, an upper part of the silicon film 107 in the p-FET region R2 is etched away by about 25 nm using a photoresist film 124 having an opening only above the p-FET region R2 as a mask. As a result, a step is formed in part of the silicon film 107 at a boundary between the n- FET region R1 and the p-FET region R2 defined by the photoresist film 124.

In the present embodiment, the silicon film 107 is isotropically etched for at least a certain period of time during the step of etching the silicon film 107, for example, by using CF₄ gas as an etching gas. As a result, the step formed in the silicon film 107 is provided with an overhang 107a protruding toward the p-FET region R2.

After the photoresist film 124 is removed, in the step of FIG. 6, a nickel film having a thickness of 35 nm, for example, is deposited as a metallic film 115 on the silicon film 107 to be the gate electrode and the interlayer insulating film 109, for example, by sputtering.

In general, step coverage of the sputtering process or the like for depositing the metallic film is poor. Therefore, if the step formed in the silicon film 107 (an underlayer of the metallic film 115) has the overhang 107a, the metallic film 115 is deposited more thinly than on the other parts or not deposited at all on the riser of the step or part of the silicon film 107 below the overhang 107a. FIG. 6 shows an example in which the metallic film 115 is not deposited on the riser of the step or the part of the silicon film 107 below the overhang 107a, i.e., part of the metallic film 115 on the n-FET region R1 is separated from part of the metallic film 115 on the p-FET region R2. Different from the example of FIG.6, the metallic film 115 may be deposited thinly on the riser of the step or the part of the silicon film 107 below the overhang 107a to connect the parts of the metallic film 115 on the n- and p-FET regions R1 and R2.

Then, in the step shown in FIG. 7, rapid thermal annealing (RTA), for example, is performed to cause reaction between the silicon film 107 and the metallic film 115. Thus, a first conductor 116 having a FUSI structure of NiSi is formed in the n-FET region R1 and a second conductor 117 having a FUSI structure of NiₓSi (x>1) is formed in the p-FET region R2.

While part of the silicon film 107 in the p-FET region R2 is thinner than part of the silicon film 107 in the n-FET region R1, the parts of the metallic film 115 deposited on the silicon film 107 in the n- and p-FET regions have the same thickness. Therefore, if the thicknesses of the silicon film 107 and the metallic film 115 are controlled such that the Ni/Si ratio in the first conductor 116 in the n-FET region R1 will be 1, the second conductor 117 in the p-FET region R2 will have the Ni/Si ratio larger than 1. The composition of the second conductor 117 is preferably Ni₃Si or Ni₂Si in view of its characteristic, but the present invention is not limited thereto.

The first conductor 116 is thicker than the second conductor 117 and the step is formed at a boundary therebetween. The step has an overhang 118A (part of the first conductor 116) in the same shape as the overhang 107a of the silicon film 107. Further, an intermediate phase region 120 is formed on part of the isolation region 102 at the boundary between the n- and p-FET regions R1 and R2. Specifically, the intermediate phase region 120 is formed between the first and second conductors 116 and 117 and has an intermediate composition between compositions of the first and second conductors 116 and 117 (intermediate composition between NiSi and Ni₃Si or Ni₂Si, for example). Then, unreacted part of the metallic film 115 is removed by etching, for example, using a mixture solution of sulfuric acid and hydrogen peroxide solution.

Since the thickness of the silicon film 107 on the p-FET region R2 is reduced in the step shown in FIG. 5, the ratio between the thickness of the silicon film 107 and the thickness of the metallic film 115 in the n-FET region R1 is varied from that in the p-FET region R2. As a result, a gate electrode 106 including the first and second conductors 116 and 117 having different silicide compositions from each other is formed in a single silicidation step. The first and second conductors 116 and 117 are electrically connected to each other to have the same potential.

In the present embodiment, the metallic film 115 is deposited more thinly than on the other parts or not deposited at all on the riser of the step formed in the silicon film 107 or part of the silicon film 107 below the overhang 107a in the step shown in FIG. 6. Therefore, the amount of metal supplied in the vicinity of the step during the silicidation, i.e., to the vicinity of the boundary between the n- and p-FET regions R1 and R2, is reduced. As a result, the occurrence of the intermediate phase region 120 is suppressed. An upper part of the intermediate phase region 120 protrudes toward the first conductor 116 for the following reason. The intermediate phase region 120 is formed as a result of diffusion of metal from part of the metallic film 115 on the silicon film 107 in the p-FET region R2 near the boundary toward the silicon film 107 in the n-FET region R1. In this step, metal is diffused isotropically from the metallic film deposited on the riser of the step formed at the boundary between the n- and p- FET regions R1 and R2.

FIG. 7 shows an example in which the overhang 118A is formed in a range from the top surface of the first conductor 116 to the top surface of the second conductor 117 just like the example shown in FIG. 1. If a timing or period for isotropically etching the silicon film 107 in the p-FET region R2 is controlled in the etching step of FIG. 5, an overhang 118B is formed only near the top surface of the first conductor 116 as shown in FIG. 2 or an overhang 118C having a square cross section is formed as shown in FIG. 3.

Though not shown, an interlayer insulating film is deposited on the gate electrode 106 and contact holes and wires are formed by a known method.

According to the method for manufacturing the semiconductor device of the present embodiment, the metallic film 115 is deposited more thinly than on the other parts or not deposited at all on the riser of the step formed in the silicon film 107 at a boundary between parts of the silicon film 107 to become the conductors 116 and 117. Therefore, the amount of metal supplied to the vicinity of the boundary during the silicidation is reduced and the occurrence of the intermediate phase region 120 is suppressed. Therefore, variations in threshold voltage of the FET are reduced without increasing the circuit area. This makes it possible to improve the performance of the semiconductor device and integrate the semiconductor device to a higher degree.

According to the method of the present embodiment, the occurrence of the intermediate phase region 120 due to the metal diffusion is suppressed, for example, by a simple means of providing the overhang 118A in the silicon film 107 at a boundary between parts of the silicon film 107 to become the conductors 116 and 117 prior to the deposition of the metallic film 115.

In the present embodiment, NiSi and Ni₃Si or Ni₂Si are used as the first conductor 116 and the second conductor 117, respectively. The material for the conductors may be other nickel silicides having different composition. The effect of the present invention is obtained even if silicides made of different metals such as NiSi and PtSi are used.

In the present embodiment, both of the first and second conductors 116 and 117 are fully silicided. However, only one of the first and second conductors 116 and 117 may be fully silicided.

In the present embodiment, the overhang 118 is configured to have a sectional shape depicted with straight lines only as shown in FIGS. 1 to 3. However, the effect of the present invention is also achieved even if the overhang 118 is configured to have a curved portion or be rounded entirely when viewed in section.

In the present embodiment, it is preferable that the overhang 118 is formed continuously along the boundary of the first and second conductors 116 and 117. However, the effect of the present embodiment is obtained to a certain degree as long as the overhang 118 is formed at least at part of the boundary.

The present embodiment is an example in which the present invention is applied to a FET gate electrode. Even if the present invention is applied to other elements using a FUSI conductor, such as a resistance element, a fuse element or an interactive interconnection, the effect of the present embodiment is obtained.

What is claimed is:

1. A semiconductor device comprising:
a first conductor and a second conductor electrically connected to each other to have the same potential, wherein
at least one of the first and second conductors has a fully silicided (FUSI) structure and
a step having an overhang is formed at least at part of a boundary between the first and second conductors.

2. The semiconductor device of claim 1, wherein
a region having an intermediate composition between compositions of the first and second conductors is interposed between the first and second conductors.

3. The semiconductor device of claim 1, wherein
the first conductor has a first FUSI structure of NiSi and the second conductor has a second FUSI structure of NiₓSi (x>1).

4. The semiconductor device of claim 1, wherein
the first and second conductors are gate electrodes of MISFETs.

5. The semiconductor device of claim 4, wherein
the gate electrodes are formed on a gate insulating film having a high dielectric constant.

6. The semiconductor device of claim 1, wherein
the first and second conductors are fuse elements or resistance elements.

7. A method for manufacturing a semiconductor device having a first conductor and a second conductor electrically connected to each other to have the same potential, the method comprising the steps of:
(a) forming a silicon film on a substrate;
(b) shaping the silicon film into a pattern including parts to become the first and second conductors;
(c) reducing a thickness of the part of the silicon film to become the second conductor after the step (b);
(d) forming a metallic film on the silicon film after the step (c); and
(e) reacting the metallic film with the silicon film by thermal treatment to cause full silicidation of at least the part of the silicon film to become the second conductor after the step (d), wherein
in the step (d), the metallic film is deposited more thinly than on the other parts or not deposited at all on a riser of a step formed in the silicon film in the step (c).

8. The method of claim 7, wherein the step formed in the silicon film in the step (c) has an overhang.

9. The method of claim 7, wherein the metallic film is a Ni film.
